(19) United States
(12) Patent Application Publication
(10) Pub. No.: US 2010/0244108 A1
(43) Pub. Date: Sep. 30, 2010

(54) CMOS IMAGE SENSOR ON A SEMICONDUCTOR-ON-INSULATOR SUBSTRATE AND PROCESS FOR MAKING SAME

(76) Inventors: Glenn Eric Kohnke, Corning, NY (US); Carlo Anthony Kosik Williams, Painted Post, NY (US)

Correspondence Address: CORNING INCORPORATED, SP-TI-3-1, CORNING, NY, 14831, US

(21) Appl. No.: 12/414,884

(22) Filed: Mar. 31, 2009

(51) Int. Cl. H01L 31/101; H01L 31/0232

(52) U.S. Cl. 257/292; 438/72; 257/E31.054; 257/E31.127

(57) ABSTRACT

Methods and apparatus for producing a CMOS image sensor result in: a glass or glass ceramic substrate having first and second spaced-apart surfaces; a semiconductor layer disposed on the first surface of the glass or glass ceramic substrate; and a plurality of pixel structures formed in the semiconductor layer, each pixel structure including: at least first, second, and third semiconductor islands, each island operating as a color sensitive photo-detector and each being of a different thickness such that each is sensitive to a respective range of light wavelengths, and a fourth semiconductor island on which at least one transistor is disposed, the at least one transistor operating to at least one of buffer, select, and reset one or more of the photo-detectors.

### BACKGROUND

The present invention relates to image sensors formed of CMOS transistors and fabricated on a semiconductor-on-insulator (SOI) structures, and methods of manufacturing same.

CMOS image sensors are used for a variety of camera products such as digital still cameras, cell phone cameras, automotive cameras and security cameras. CMOS technology is attractive for use in such applications because CMOS transistors exhibit low power consumption characteristics and are fabricated at relatively low manufacturing costs. The achievable pixel size of CMOS image sensors has been steadily decreasing as the technology matures and, thus, higher resolution images are available from increasingly smaller camera product packages. As the pixel size decreases, however, there is a corresponding degradation in the photodiode sensitivity of each pixel, lowering of optical collection efficiency, and increased electrical crosstalk within and between pixels. In addition, the red/green/blue color filtering function (color separation) becomes more challenging as the pixel size decreases.

The above problems are typically associated with a conventional CMOS image sensor that has been fabricated in bulk silicon. There has been some effort in the prior art to develop CMOS image sensors having various pixel structures to address one or more of these problems. Such pixel structures include the use of silicon on a transparent insulator substrate to allow for reduced electrical crosstalk and improved optical collection efficiency. In another case, an improvement in resolution attributable to the color separation function was achieved using vertically stacked wavelength sensor layers in a bulk silicon wafer.

The prior art attempts to address the problems of lower photodiode sensitivity, lower optical collection efficiency, increased electrical crosstalk, and poor color separation in CMOS image sensors, while admirable, have not addressed enough of the problems in one, integrated solution. Thus, there are needs in the art for new methods and apparatus for fabricating CMOS image sensors.

### SUMMARY

In accordance with one or more embodiments disclosed herein, methods and apparatus result in novel CMOS pixel structures fabricated on SOI substrates, such as silicon on glass ceramic (SiOGC), a novel color separation technique, and an integrated retro-reflection technique, all of which collectively address the issues of photodiode sensitivity, optical collection efficiency, electrical crosstalk, and color separation.

Methods and apparatus provide for a CMOS image sensor, comprising: a glass or glass ceramic substrate having first and second spaced-apart major surfaces; a semiconductor layer disposed on the first surface of the glass or glass ceramic substrate; and a plurality of pixel structures formed in the semiconductor layer. Each pixel structure may include: at least first, second, and third semiconductor islands, each island operating as a color sensitive photo-detector and each being of a different thickness such that each is sensitive to a respective range of light wavelengths, and a fourth semiconductor island on which at least one transistor is disposed, the at least one transistor operating to at least one of buffer, select, and reset one or more of the photo-detectors.

The first semiconductor island may be of a first thickness, between about 0.05 um and about 1.80 um, for detecting blue light. The second semiconductor island may be of a second thickness between about 0.20 um and about 4.70 um for detecting composite blue and green light. The third semiconductor island may be of a third thickness between about 0.55 um and about 12.10 um for detecting composite blue and green and red light. These thicknesses assume that the light is absorbed by somewhere between about 10% on the low side and 90% on the high side in one pass of the light into the respective semiconductor islands.

A retro-reflector may be employed to reflect light that propagates through a second surface of the glass or glass ceramic substrate, opposite to the first surface thereof, and through at least one of the first, second, and third semiconductor islands, at least partially back therethrough. The retro-reflector improves light absorptions characteristics of the pixel structures and may, among other things, permit a reduction in the thicknesses of the first, second, and third semiconductor islands. For example, the above ranges of thickness may be reduced by a factor of about ½. The retro-reflector may be implemented via contact metallization layer(s) disposed on the first, second, and/or third semiconductor islands.

The semiconductor layer of the CMOS image sensor may be formed from a first semiconductor layer bonded to the first surface of the glass or glass ceramic substrate via anodic bonding and a second semiconductor layer formed on the first semiconductor layer via epitaxial growth.

The substrate of the CMOS image sensor may be a glass ceramic substrate, operating to withstand CMOS processing temperatures of at least 950° C. or more.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1A is a block diagram illustrating the structure of a CMOS image sensor formed on an SOG substrate in accordance with one or more embodiments of the present invention;

FIG. 1B is a schematic diagram of a circuit suitable for implementing a given pixel structure of the CMOS image sensor of FIG. 1;

FIG. 1C is a block diagram illustrating the pixel structure of the CMOS image sensor of FIG. 1A;

FIGS. 2-5 are block diagrams of intermediate structures formed using a fabrication process to achieve a SOG foundation structure suitable for use in constructing the CMOS image sensor of FIG. 1A; and

FIGS. 6-8 are block diagrams of intermediate structures achieved using a process for forming each pixel of the CMOS image sensor.

### DETAILED DESCRIPTION

A CMOS image sensor in accordance with various aspects of the present invention may be implemented in a semiconductor material, such as silicon, using CMOS very-large-scale-integration (VLSI) compatible fabrication processes. One or more embodiments disclosed herein contemplate the implementation of a CMOS image sensor on an SOG substrate, such as a silicon on glass ceramic (SiOGC) substrate. The SOG substrate is compatible with CMOS fabrication process steps, and permits color-selective sub-pixel photodetectors and readout transistor circuitry to be implemented in the semiconductor (e.g., silicon) layer. The transparent glass (or glass ceramic) portion of the SOG supports backside illumination and the benefits thereof.

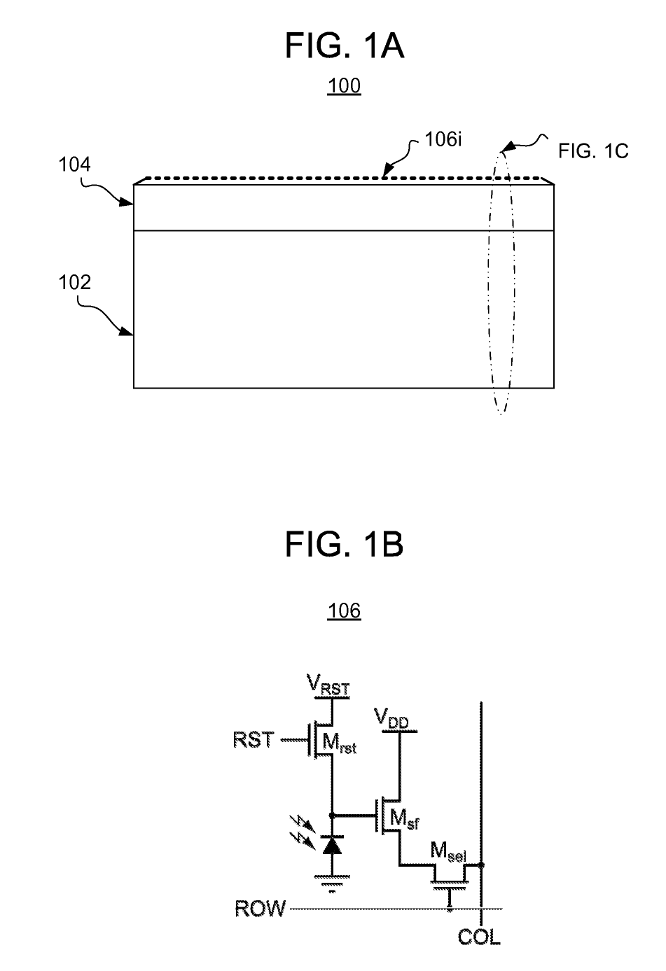

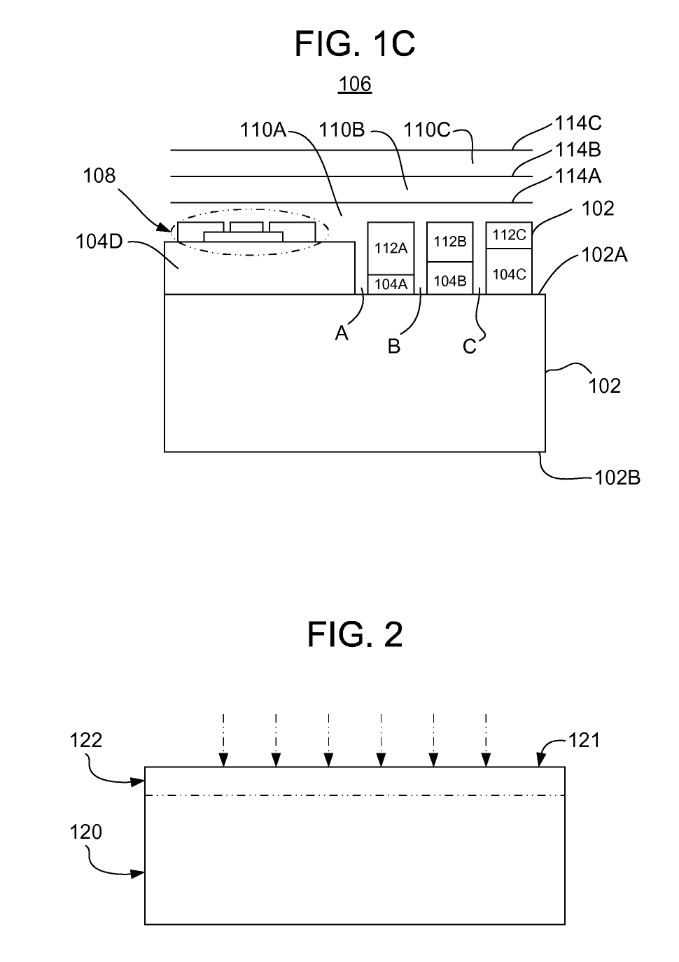

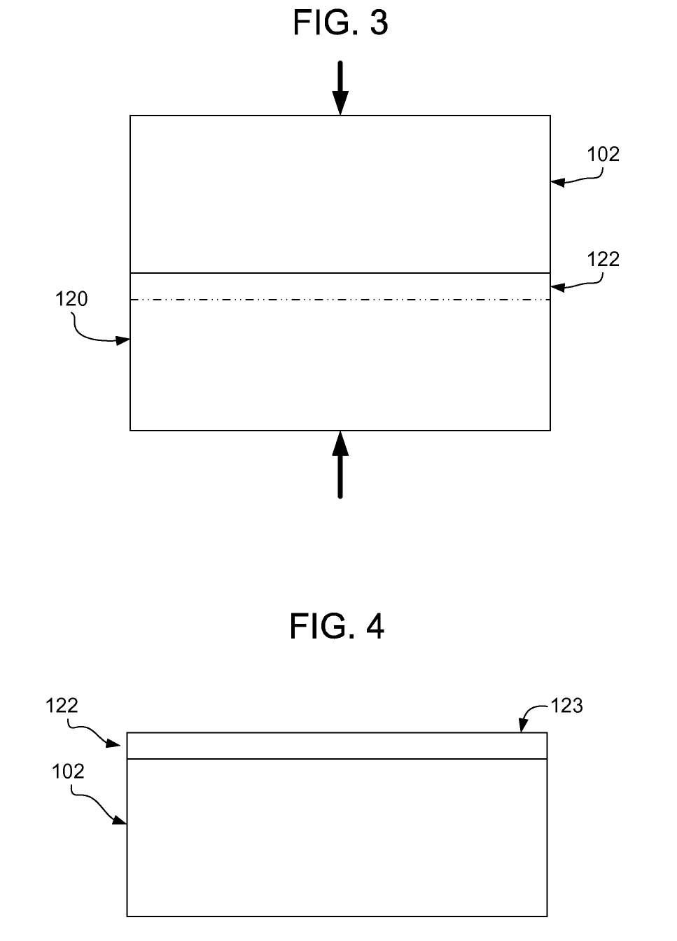

With reference to the drawings, wherein like numerals indicate like elements, there is shown in FIG. 1A a CMOS image sensor 100 formed on a SOG structure in accordance with one or more embodiments of the present invention. The CMOS image sensor 100 includes a glass or glass ceramic substrate 102, and a semiconductor layer 104. A plurality of CMOS image sensor pixel structures 106i are disposed on and/or within the semiconductor layer 104 of the CMOS image sensor 100.

By way of example, and not limitation, a circuit diagram of a pixel structure 106 suitable for implementing a given one of the pixel structures 106 is illustrated in FIG. 1B. The circuitry for implementing a CMOS image sensor pixel may be a so-called 3T cell, including a photo-detector (such as a JFET photogate or pinned photodiode), a transfer gate, a reset gate, and a row select transistor. A first transistor, Mᵣₛₜ, acts as a switch to reset the pixel cell. When the Mᵣₛₜ transistor is turned on, the photodiode is effectively connected to the power supply, V_{RST}, clearing all integrated charge. The second transistor, M_{sf}, acts as a buffer, specifically, a source follower amplifier, which allows the pixel voltage to be measured without removing any accumulated charge. The power supply, V_{DD}, of the M_{sf} transistor may be tied to the power supply of the Mᵣₛₜ transistor. The third transistor, Mₛₑₗ, is the row-select transistor, which operates as a switch that allows a single row of the pixel array to be read by read-out electronics (not shown). It is understood that alternative pixel circuit implementations are permitted without departing from the scope of the embodiments disclosed herein.

With reference to FIGS. 1A and 1C, a cross-section of a given pixel structure 106 is illustrated in detail. The pixel structure 106 includes a portion of the glass or glass ceramic substrate 102 having first and second spaced-apart major surfaces 102A, 102B. A section of the semiconductor layer 104 is disposed on the first surface 102A of the glass or glass ceramic substrate 102. The section of the semiconductor layer 104 includes at least first, second, and third semiconductor islands 104A, 104B, and 104C, each island operating as a color sensitive photo-detector. As will be discussed in more detail below, each semiconductor island 104A, 104B, and 104C may be of a different thickness such that each island is sensitive to a respective range of light wavelengths. A fourth semiconductor island 104D is also disposed on the first surface 102A of the glass or glass ceramic substrate 102, and includes at least one transistor 108 operating to at least one of buffer, select, and reset one or more of the photo-detectors. In other words, the at least one transistor 108 operates to carry out one or more of the functions of a particular circuit implementation of the pixel structure 106, such as that discussed above with respect to FIG. 1B.

The first, second, third, and fourth semiconductor islands 104A, 104B, 104C, and 104D are isolated from one another via physical trenches A, B, C, which may include a dielectric material, such as silica, disposed therein. The particular thicknesses of the first, second, and third semiconductor islands 104A, 104B, and 104C are established to create color sensitivity in the photo-detection function. The first semiconductor island 104A may be of a first thickness, between about 0.05 um and about 1.80 um, for detecting blue light. The second semiconductor island 104B may be of a second thickness between about 0.20 um and about 4.70 um for detecting composite blue and green light. The third semiconductor island 104C may be of a third thickness between about 0.50 um and about 12.10 um for detecting composite blue and green and red light. These thicknesses assume that the light is absorbed by somewhere between about 10% on the low side and 90% on the high side in one pass of the light into the respective semiconductor islands.

With the above configuration, light is received into the pixel structure 106 via the second surface 102B of the glass or glass ceramic substrate 102. The light then enters into the respective first, second, and third semiconductor islands (photo-detectors) 104A, 104B, 104C and is absorbed and sensed. Electrical connections to the respective photo-detectors 104A, 104B, 104C is achieved by respective contact metallization 112A, 112B, 112C disposed thereon. Electrical connections to the contact metallization 112 and the transistors 108 is achieved via one or more layers of interconnection metallization 114A, 114B, 114C, including further dielectric material layers 110A, 110B, 110C therebetween.

In one or more embodiments, one or more of the contact metallization 112A, 112B, 112C may operate as a retro-reflector. The retro-reflector reflects light that has propagated through the second surface 102B of the glass or glass ceramic substrate 102, and through at least one of the first, second, and third semiconductor islands 104A, 104B, 104C at least partially back therethrough. Using this configuration, the light absorption characteristics of the photo-detectors is improved and the thicknesses of the semiconductor islands 104A, 104B, 104C may be reduced (by somewhere up to about ½) without sacrificing sensing quality. For example, using a retro-reflector, the first semiconductor island 104A may be between about 0.025 um and about 0.90 um thick and detect blue light. The second semiconductor island 104B may be between about 0.10 um and about 2.35 um thick and detect composite blue and green light. The third semiconductor island 104C may be between about 0.25 um and about 6.0 um thick and detect composite blue and green and red light.

In one or more embodiments, the substrate 102 is a glass ceramic substrate. The glass ceramic substrate 102 is alkali-free, and expansion-matched to the semiconductor layer 104. The glass-ceramic substrate 102 possess excellent thermal stability, and maintains transparency and dimensional stability for many hours at temperatures in excess of 950° C., which is desirable for relatively high temperature CMOS processes. The material also provides excellent chemical durability to resist the etchants used in the CMOS fabrication process. Additionally, any metal ions in the glass ceramic substrate 102 pose a negligible contamination threat during the CMOS fabrication process at elevated temperatures. Modifier ions are also trapped in the glass ceramic substrate 102 and cannot migrate into the semiconductor layer 104, which might otherwise degrade the electrical and/or optical characteristics of the pixel structures 106.

It is noted that lower temperature CMOS processes are available, which may be used when certain glass substrates 102 are employed that are less stable at higher CMOS processing temperatures, such as 950° C. or greater. Such glasses include EAGLE XG™ and JADE™ available from Corning Incorporated, Corning, N.Y., each of which have strain points of less than about 700° C. The lower temperature CMOS processes, however, usually result in lower electrical and/or optical performance.

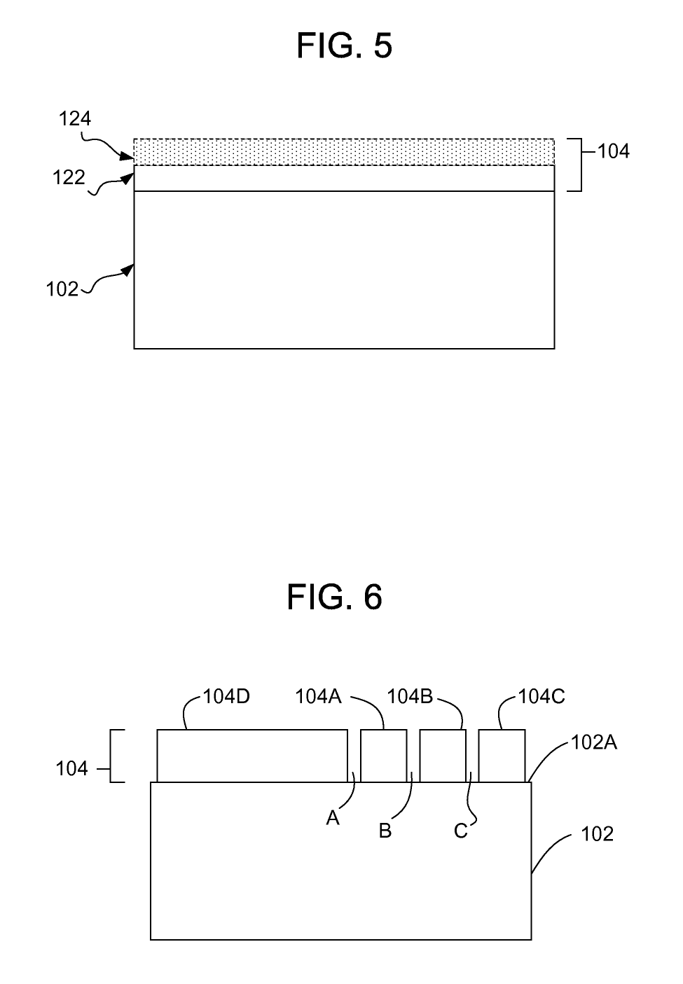

Reference is now made to FIGS. 2-8, which illustrate processes and structures useful in implementing one or more embodiments of the CMOS image sensor 100. FIGS. 2-5 are block diagrams of intermediate structures formed using a fabrication process to achieve a SOG foundation structure suitable for use in constructing the CMOS image sensor 100. The foundation structure is shown in FIG. 5 and includes the glass or glass ceramic substrate 102 and the semiconductor layer 104 bonded thereto.

The semiconductor layer 104 may be bonded to the glass substrate 102 using any of the existing techniques. Among the suitable techniques is bonding using an electrolysis process. A suitable electrolysis bonding process is described in U.S. Pat. No. 7,176,528, the entire disclosure of which is hereby incorporated by reference. Portions of this process are discussed below.

With reference to FIG. 2, a semiconductor donor wafer 120 is subject to ion implantation, such as hydrogen and/or helium ion implantation, to create a zone of weakness below a bonding surface 121 of the semiconductor donor wafer 120.

The semiconductor material of the semiconductor donor wafer 120 (and thus the semiconductor layer 104) may be in the form of a substantially single-crystal material. The term “substantially” is used to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material.

For the purposes of discussion, it is assumed that the semiconductor material of the semiconductor donor wafer 120 (and thus the semiconductor layer 104) is formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, GaN, and InP.

The substrate 102 may be formed from an oxide glass or an oxide glass-ceramic. By way of example, the glass substrate 102 may be formed from glass substrates containing alkaline-earth ions and may be silica-based, such as, substrates made of CORNING INCORPORATED GLASS COMPOSITION NO. 1737 or CORNING INCORPORATED GLASS COMPOSITION NO. EAGLE 2000®. The glass or glass-ceramic substrate 102 may be designed to match a coefficient of thermal expansion (CTE) of one or more semiconductor materials (e.g., silicon, germanium, etc.) of the layer 104 that are bonded together. The CTE match ensures desirable mechanical properties during heating cycles of the deposition process.

With reference to FIG. 2-3, the glass or glass ceramic substrate 102 and the bonding surface 121 (FIG. 2) of the donor semiconductor wafer 120 are brought into direct or indirect contact and are heated under a differential temperature gradient. Mechanical pressure is applied to the intermediate assembly (e.g., about 1 to about 50 psi.) and the structure is taken to a temperature within about ±150 degrees C. of the strain point of the glass or glass ceramic substrate 102. A voltage is applied with the donor semiconductor wafer 120 at a positive potential and the glass or glass ceramic substrate 102 a negative potential. The intermediate assembly is held under the above conditions for some time (e.g., approximately 1 hour or less), the voltage is removed, and the intermediate assembly is allowed to cool to room temperature.

With reference to FIG. 4, at some point during the above process, the donor semiconductor wafer 120 and the glass or glass ceramic substrate 102 are separated, to obtain a glass or glass ceramic substrate 102 with a relatively thin exfoliation layer 122 of the semiconductor material bonded thereto. The separation of the donor semiconductor wafer 120 from the exfoliation layer 122 that is bonded to the glass or glass ceramic substrate 102 is accomplished through application of stress to the zone of weakness within the donor semiconductor wafer 120, such as by a heating and/or cooling process. It is noted that the characteristics of the heating and/or cooling process may be established as a function of a strain point of the glass or glass ceramic substrate 102. Although the invention is not limited by any particular theory of operation, it is believed that glass or glass ceramic substrates 102 with relatively low strain points may facilitate separation when the respective temperatures of the donor semiconductor wafer 120 and the glass or glass ceramic substrate 102 are falling or have fallen during cooling. Similarly, it is believed that glass or glass ceramic substrates 102 with relatively high strain points may facilitate separation when the respective temperatures of the donor semiconductor wafer 120 and the glass or glass ceramic substrate 102 are rising or have risen during heating. Separation of the donor semiconductor wafer 120 and the glass or glass ceramic substrate 102 may also occur when the respective temperatures thereof are neither substantially rising nor falling (e.g., at some steady state or dwell situation).

In the case of glass substrates 102, the application of the electrolysis bonding process causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer in the glass substrate 102 adjacent the semiconductor/glass interface; and (2) an enhanced positive ion concentration layer of the glass substrate 102 adjacent the reduced positive ion concentration layer. This accomplishes a number of features: (i) an alkali or alkaline earth ion free interface (or layer) is created in the glass substrate 102; (ii) an alkali or alkaline earth ion enhanced interface (or layer) is created in the glass substrate 102; (iii) an oxide layer is created between the exfoliation layer 122 and the glass substrate 102; and (iv) the glass substrate 102 becomes very reactive and bonds to the exfoliation layer 122 strongly with the application of heat at relatively low temperatures. Additionally, relative degrees to which the modifier positive ions are absent from the reduced positive ion concentration layer in the glass substrate 102, and the modifier positive ions exist in the enhanced positive ion concentration layer are such that substantially no ion re-migration from the glass substrate 102 into the exfoliation layer 122 (and thus into any of the structures later formed thereon or therein).

An alternative embodiment may include further processing steps to transform a glass substrate into a glass-ceramic substrate 102. In this regard, the structure of FIG. 4 is treated as an intermediate structure in which the glass substrate 102 is a (precursor) glass substrate 102. The precursor glass substrate 102 is cerammed via a heat treatment step in an inert atmosphere such as argon. The ceramming or heat-treatment step generally follows a heat treatment cycle where the intermediate structure is held at a certain temperature to nucleate the crystals of the precursor glass substrate 102 followed by a higher temperature hold for crystal growth. In an alternative embodiment, a heat treatment that does not involve nucleation hold temperature may be utilized. In such an embodiment the ramp up schedule to the crystal growth hold temperature is sufficiently slow to achieve the necessary nucleation of the crystals, for example, a rate no greater than about 50° C./hr.

As a result of the above-described heat-treatment, a portion of the precursor glass substrate 102 remains glass and a portion is converted to a glass-ceramic structure. Specifically, the portion which remains an oxide glass is that portion of the precursor glass substrate 102 closest to the semiconductor exfoliation layer 122, the aforementioned reduced positive ion concentration layer. This is due to the fact that there is a lack of spinel forming cations Zn, Mg in this portion of the precursor glass substrate 102 (because the positive modifier ions moved away from the interface during the bonding process). At some depth into the precursor glass substrate 102 (specifically that portion of the precursor glass substrate 102 with an enhanced positive ion concentration) there are sufficient ions to enable crystallization and to form a glass-ceramic layer with an enhanced positive ion concentration.

It follows that the remaining precursor glass portion 102 (a bulk glass portion at still further depths into the substrate 102 away from the interface) also possesses sufficient spinel forming cations to achieve crystallization. The resultant glass-ceramic substrate structure is thus a two layer glass-ceramic portion comprised of a layer having an enhanced positive ion concentration, which is adjacent the remaining oxide glass layer, and a bulk glass-ceramic layer.

Irrespective of whether one employs a glass substrate 102 or a cerammed substrate, the cleaved surface 123 of the SOI structure just after exfoliation may exhibit excessive surface roughness, implantation damage, etc. Post processing may be carried out to correct the roughness, implantation damage, etc.

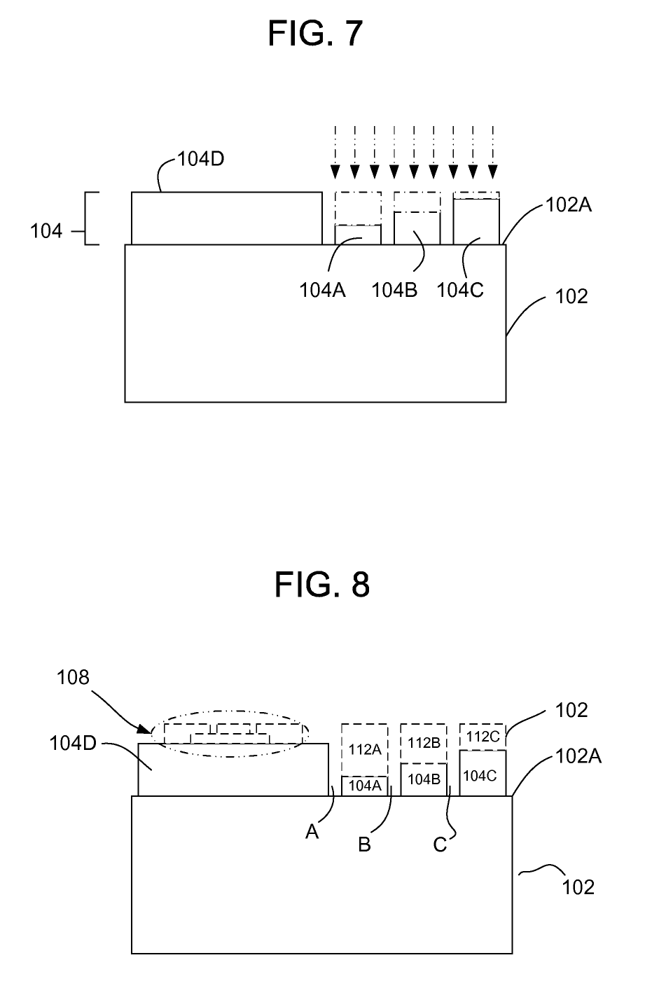

With reference to FIGS. 5-6, it is possible that the thickness of the exfoliation layer 122 may be on the order of less than about 1 um. As the thicknesses of at least some of the semiconductor islands 104A, 104B, 104C may be greater than 1 um for efficient light absorption, the process may include forming the final semiconductor layer 104 by thickening the exfoliated semiconductor layer 122 to a thickness greater than 1 uM. This may be carried out by disposing a further semiconductor layer 124 on the exfoliated semiconductor layer 122 via epitaxial growth. Any of the known or hereinafter developed processes for epitaxial growth on an existing semiconductor layer may be employed. The resultant final semiconductor layer 104 is thus a first semiconductor layer 122 bonded to the first surface 102A of the glass or glass ceramic substrate 102 via anodic bonding and a second semiconductor layer 124 formed on the first semiconductor layer 122 via epitaxial growth.

FIGS. 6-8 are block diagrams of intermediate structures achieved using a process for forming each pixel 106 of the CMOS image sensor 100. With reference to FIG. 6, each pixel structure 106 is formed by isolating the first, second, third and fourth semiconductor islands 104A, 104B, 104C and 104D using vertical preferential etching. The specific process steps in achieving island isolation in semiconductor materials are well known in the art and may applied here to achieve deep trench isolation in the semiconductor layer 104, such as vertical preferential etching extending to about 7 um deep.

With reference to FIG. 7, a process of thinning at least one of the first, second, and third semiconductor islands 104A, 104B, 104C is performed such that each is of a different thickness. A known or hereinafter developed semiconductor etch process may be used to achieve the desired thickness of each island. As discussed above, the thickness is selected such that each island 104A, 104B, 104C operates as a color sensitive photo-detector sensitive to a respective range of light wavelengths.

With reference to FIG. 8, known processes may be carried out to form the at least one transistor 108 (such as a thin-film-transistor, TFT) on the fourth semiconductor island 104D in order to obtain the proper circuitry for buffering, selecting, and resetting the photo-detectors. Turing again to FIG. 1C, the dielectric material, such as silica, may then be applied to electrically isolate the semiconductor islands 104A, 104B, 104C and prevent electrical cross-talk between the photo-detectors within a given pixel and between pixel structures. Further dielectric layers 110B, 110C and metallization layers 114A, 114B, 114C are deposited using known semiconductor fabrication techniques to achieve the final structure 100. The above fabrication techniques may include subjecting the semiconductor layer 104 to patterned oxide and metal deposition procedures (e.g., etching techniques) and doping using ion shower techniques (and or any of the other known techniques). Inter-layers, contact holes, and metal contacts may be disposed using known fabrication techniques to produce the CMOS image sensor 100.

In summary, embodiments disclosed herein may be directed to CMOS image sensor applications. Among the advantages of at least some of the embodiments disclosed herein include:
Reducing or eliminating the need for an external color filter as color separation may be achieved via semiconductor thickness of at least three semiconductor islands within each pixel. Embodiments employing greater than three photo-detectors within each pixels are capable of being produced, which would allow for an enhanced color capture capability. The use of semiconductor island thicknesses to detect primary colors, for example, blue, blue+green, and blue+green+red, offers the advantage of reduced noise due to larger absorption/increased current compared with individual blue, green, and red sensitive pixels.
Reducing or eliminating the need for complicated waveguide/light-pipe structures to efficiently couple light to the photo-detectors due to the use of backside illumination, through the second surface of the glass or glass ceramic substrate. The backside illumination may also relax strict requirements to have low metallization stack-up height.
Reducing or eliminating intra- and/or inter-pixel cross-talk through the use of the isolated photo-detector islands and the insulating glass or glass ceramic substrate.
Increasing photo-detection efficiency and/or reducing the thickness of the photo-detector islands through the use of the retro-reflector (such as an appropriate contact metal).
The pixel structure permits for a decrease in the size of each pixel and ultimately higher image pixel count (e.g., five mega-pixels and higher) without a compromise in image quality.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A CMOS image sensor, comprising:
a glass or glass ceramic substrate having first and second spaced-apart surfaces;
a semiconductor layer disposed on the first surface of the glass or glass ceramic substrate; and
a plurality of pixel structures formed in the semiconductor layer, each pixel structure including:
a plurality of semiconductor islands, each island operating as a color sensitive photo-detector and each being of a different thickness such that each is sensitive to a respective range of light wavelengths, and
a further semiconductor island on which at least one transistor is disposed, the at least one transistor operating to buffer, select, or reset one or more of the photo-detectors.

2. The CMOS image sensor of claim 1, wherein:
the plurality of semiconductor islands include at least first, second, and third semiconductor islands, and the further semiconductor island is a fourth semiconductor island;
the first semiconductor island is of a first thickness for detecting blue light;
the second semiconductor island is of a second thickness for detecting composite blue and green light; and
the third semiconductor island is of a third thickness for detecting composite blue and green and red light.

3. The CMOS image sensor of claim 2, wherein:
the first thickness is between about 0.05 um and about 1.80 um;
the second thickness is between about 0.20 um and about 4.70 um; and
the third thickness is between about 0.50 um and about 12.10 um.

4. The CMOS image sensor of claim 3, wherein:
the first thickness is between about 0.025 um and about 0.90 um;
the second thickness is between about 0.10 um and about 2.35 um; and
the third thickness is between about 0.25 um and about 6.0 um.

5. The CMOS image sensor of claim 4, further comprising a retro-reflector operating to reflect light that has propagated through the second surface of the glass or glass ceramic substrate, and through at least one of the first, second, and third semiconductor islands, at least partially back therethrough.

6. The CMOS image sensor of claim 4, wherein the retro-reflector includes a contact metallization layer disposed on the at least one of the first, second, and third semiconductor islands.

7. The CMOS image sensor of claim 1, wherein the semiconductor layer is formed from a first semiconductor layer bonded to the first surface of the glass or glass ceramic substrate via anodic bonding and a second semiconductor layer formed on the first semiconductor layer via epitaxial growth.

8. The CMOS image sensor of claim 7, wherein:
at least one of the first and second semiconductor layers is formed from a single crystal semiconductor material; and
the single crystal semiconductor material is taken from the group consisting of: silicon (Si), germanium-doped silicon (SiGe), silicon carbide (SiC), germanium (Ge), gallium arsenide (GaAs), GaP, GaN, and InP.

9. The CMOS image sensor of claim 1, wherein the substrate is a glass substrate and includes:
a first layer adjacent to the semiconductor layer with a reduced positive ion concentration having substantially no modifier positive ions; and
a second layer adjacent to the first layer with an enhanced positive ion concentration of modifier positive ions, including at least one alkaline earth modifier ion from the first layer.

10. The CMOS image sensor of claim 9, wherein relative degrees to which the modifier positive ions are absent from the first layer and the modifier positive ions exist in the second layer are such that substantially no ion re-migration from the glass substrate into the semiconductor layer may occur.

11. The CMOS image sensor of claim 1, wherein the substrate is a glass ceramic substrate operating to withstand CMOS processing temperatures of at least 950° C.

12. A method of forming a CMOS image sensor, comprising:
bonding a semiconductor donor wafer to a first surface of a glass or glass-ceramic substrate using an anodic bonding process;
separating the semiconductor donor wafer from the glass or glass-ceramic substrate leaving an exfoliated semiconductor layer bonded thereto;
forming a final semiconductor layer by thickening the exfoliated semiconductor layer to a thickness greater than 1 um; and
forming a plurality of pixel structures in the final semiconductor layer, each pixel structure being formed by:
isolating a plurality of semiconductor islands using vertical preferential etching,
thinning at least some of the semiconductor islands such that some of the semiconductor islands are of a different thickness and such that each operates as a color sensitive photo-detector sensitive to a respective range of light wavelengths, and
forming at least one transistor on a further semiconductor island, the at least one transistor operating to at least one of buffer, select, and reset one or more of the photo-detectors.

13. The method of claim 12, wherein:
the plurality of semiconductor islands include at least first, second, and third semiconductor islands; and
the step of thinning includes at least one of reducing the thickness of at least one of:
the first semiconductor island to a first thickness between about 0.05 um and about 1.80 um for detecting blue light;
the second semiconductor island to a second thickness between about 0.20 um and about 4.70 um for detecting composite blue and green light; and
the third semiconductor island to a third thickness between about 0.50 um and about 12.10 um for detecting composite blue and green and red light.

14. The method of claim 13, wherein:
at least one of: (i) the first thickness is between about 0.025 um and about 0.90 um, (ii) the second thickness is between about 0.10 um and about 2.35 um, and (iii) the third thickness is between about 0.25 um and about 6.0 um; and
the method further comprises forming a retro-reflector on at least one of the first, second, and third semiconductor islands, the retro-reflector operating to reflect light that propagates through a second surface of the glass or glass ceramic substrate, opposite to the first surface thereof, and through at least one of the first, second, and third semiconductor islands, at least partially back therethrough.

15. The method of claim 14, wherein the step of forming the retro-reflector includes disposing a contact metallization layer on the at least one of the first, second, and third semiconductor islands.

16. The method of claim 12, wherein the step of thickening the exfoliated semiconductor layer includes disposing a further semiconductor layer on the exfoliated semiconductor layer via epitaxial growth.

17. The method of claim 12, wherein:
the substrate is a glass substrate;
the bonding process includes applying heat, pressure and voltage to the semiconductor donor wafer and the glass substrate such that:
a first layer of the glass substrate adjacent to the exfoliated semiconductor layer includes a reduced positive ion concentration having substantially no modifier positive ions; and
a second layer of the glass substrate adjacent to the first layer includes an enhanced positive ion concentration of modifier positive ions, including at least one alkaline earth modifier ion from the first layer.

18. The method of claim 17, wherein relative degrees to which the modifier positive ions are absent from the first layer and the modifier positive ions exist in the second layer are such that substantially no ion re-migration from the glass substrate into the final semiconductor layer may occur.

19. The method of claim 12, wherein the substrate is a glass ceramic substrate operating to withstand CMOS processing temperatures of at least 950° C.
